(19) United States
(12) Patent Application Publication
(10) Pub. No.: US 2019/0154748 A1
(43) Pub. Date: May 23, 2019

(54) POWER LINE COMMMUNICATION AND REAL-TIME WIRING FAULT LOCATION

(71) Applicant: HONEYWELL INTERNATIONAL INC., Morris Plains, NJ (US)

(72) Inventors: Zhenning Liu, Mississauga (CA); Andrew Peter Vechart, Plymouth, MN (US); Raj Mohan Bharadwaj, Maple Grove, MN (US)

(73) Assignee: HONEYWELL INTERNATIONAL INC., Morris Plains, NJ (US)

(21) Appl. No.: 15/821,156

(22) Filed: Nov. 22, 2017

(51) Int. Cl. G01R 31/08; H02J 3/06

(52) U.S. Cl. CPC G01R 31/086; H02J 3/06; G01R 31/088

(57) ABSTRACT

A power line communication and real-time wiring fault location system includes a power distribution system, a plurality of solid-state power controllers, and a communication and fault location determination circuit. The power distribution system includes an upstream power feeder line and a plurality of load-end feeder lines. Each solid-state power controller is associated with a different one of the load-end feeder lines and is configured to selectively couple its associated load-end feeder line to the upstream power feeder line and detect an electrical fault on its associated load-end feeder line or in an electrical load to which the associated load-end feeder line is coupled. The communication and fault location determination circuit is coupled to each of the load-end feeder lines and is configured, in response to a channel selection command, to selectively transmit a fault location stimulation signal onto one of the load-end feeder lines.

### TECHNICAL FIELD

The present invention generally relates to power distribution systems, and more particularly relates to a power line communication and real-time wiring fault location system for power distribution systems.

### BACKGROUND

In recent years, modern aircraft are becoming increasingly reliant on electrical power. This has led to the development of advanced aircraft secondary electric power distribution systems (SEPDSs). In a typical system, electric power is delivered to various electric loads via a power feeder network (or wiring system) that links all the electric loads together in the aircraft. In some instances, power line communication (PLC) technology may allow the power feeder network to also serve as a communication network. The increased reliance on electrical power has also focused growing attention on aircraft wiring integrity to reduce the likelihood of arcing from wiring problems.

Typically, each electric load is controlled by a solid-state power controller (SSPC) in a SEPDS. The SSPCs, among other functions, constantly sample the instantaneous load current and load voltage, which can be used, along with additional information, to determine the health of the load and its associated feeder line, and to also provide arc fault detection and protection functionality.

Although arc fault detection and protection functionality is implemented in most SSPCs, finding the location of the wiring problem associated with an arc remains a challenge. Various technologies used to detect and pin-point the location of wiring problems have been proposed. Among these, spread spectrum time domain reflectometry (SSTDR) has received particular attention and has demonstrated its potential as an effective way of locating intermittent wiring problems during flight. Thus far, however, the aircraft electric power distribution systems that use SSTDR to locate wiring problems exhibit certain drawbacks. For example, the SSTDR tap point of known systems is upstream of the SSPCs. As a result, determining the location of the wiring issue (e.g., the wire fault location (WFL)) has a time constraint before the associated SSPC opens, in response to the fault, thereby also opening the SSTDR signal path. This leads to less effective and inefficient control and maintenance functions for aircraft electric loads and wiring systems.

Hence, there is a need for a practical implementation of PLC and SSTDR technologies in an aircraft electric power distribution system, and especially those systems with multiple SSPC channels, that facilitates effective and efficient control and maintenance functions for aircraft electric loads and wiring system.

### BRIEF SUMMARY

This summary is provided to describe select concepts in a simplified form that are further described in the Detailed Description. This summary is not intended to identify key or essential features of the claimed subject matter, nor is it intended to be used as an aid in determining the scope of the claimed subject matter.

In one embodiment, a power line communication and real-time wiring fault location system includes a power distribution system, a plurality of solid-state power controllers, and a communication and fault location determination circuit. The power distribution system includes an upstream power feeder line and a plurality of load-end feeder lines, and each load-end feeder line is coupled to an electrical load. Each solid-state power controller is associated with a different one of the load-end feeder lines and is coupled between its associated load-end feeder line and the upstream power feeder line. Each solid-state power controller is configured to (i) selectively couple its associated load-end feeder line to the upstream power feeder line and (ii) detect an electrical fault on its associated load-end feeder line or in the electrical load to which the associated load-end feeder line is coupled. The communication and fault location determination circuit is coupled to each of the load-end feeder lines. The communication and fault location determination circuit is adapted to receive a channel selection command and is configured, in response to the channel selection command, to selectively transmit a fault location stimulation signal onto one of the load-end feeder lines.

In another embodiment, a power line communication and real-time wiring fault location system includes a power distribution system, a plurality of solid-state power controllers, a communication and fault location determination circuit, and a supervisory processor. The power distribution system includes an upstream power feeder line and a plurality of load-end feeder lines, and each load-end feeder line is coupled to an electrical load. Each solid-state power controller is associated with a different one of the load-end feeder lines and is coupled between its associated load-end feeder line and the upstream power feeder line. Each solid-state power controller is configured to (i) selectively couple its associated load-end feeder line to the upstream power feeder line and (ii) detect an electrical fault on its associated load-end feeder line or in the electrical load to which the associated load-end feeder line is coupled. The communication and fault location determination circuit is coupled to each of the load-end feeder lines. The communication and fault location determination circuit is coupled to receive a channel selection command and is configured, in response to the channel selection command, to (i) selectively transmit a fault location stimulation signal onto one of the load-end feeder lines and (ii) receive a reflected signal from the load-end feeder line and, in response to the reflected signal, determine a location of the electrical fault. The supervisory processor is in operable communication with each of the solid-state power controllers and with the communication and fault location determination circuit, and is configured to supply the channel selection command to the communication and fault location determination circuit.

In yet another embodiment, a power line communication and real-time wiring fault location system includes a power distribution system, a plurality of solid-state power controllers, a supervisory processor, and a communication and fault location determination circuit. The power distribution system includes an upstream power feeder line and a plurality of load-end feeder lines, and each load-end feeder line is coupled to an electrical load. Each solid-state power controller is associated with a different one of the load-end feeder lines and is coupled between its associated load-end feeder line and the upstream power feeder line. Each solid-state power controller is configured to (i) selectively couple its associated load-end feeder line to the upstream power feeder line and (ii) detect an electrical fault on its associated load-end feeder line or in the electrical load to which the associated load-end feeder line is coupled. The supervisory processor is in operable communication with each of the solid-state power controllers and with the communication and fault location determination circuit, and is configured to selectively supply a channel selection command. The communication and fault location determination circuit is coupled to each of the load-end feeder lines. The communication and fault location determination circuit is coupled to receive the channel selection command and is configured, in response to the channel selection command, to: (i) selectively transmit a fault location stimulation signal onto one of the load-end feeder lines, (ii) receive a reflected signal from the load-end feeder line and, in response to the reflected signal, determine a location of the electrical fault, and (iii) selectively facilitate power line communication with one or more of the load-end feeder lines.

Furthermore, other desirable features and characteristics of the power line communication and real-time wiring fault location system will become apparent from the subsequent detailed description and the appended claims, taken in conjunction with the accompanying drawings and the preceding background.

### BRIEF DESCRIPTION OF THE DRAWINGS

The present invention will hereinafter be described in conjunction with the following drawing figures, wherein like numerals denote like elements, and wherein:

FIG. 1 depicts a functional block diagram of one embodiment of a power line communication and real-time wiring fault location system;

FIG. 2 depicts a process, in flowchart form, for wire fault location determination that the system of FIG. 1 may implement; and

FIG. 3 depicts a process, in flowchart form, that may include power line communication that the system of FIG. 1 may implement.

### DETAILED DESCRIPTION

The following detailed description is merely exemplary in nature and is not intended to limit the invention or the application and uses of the invention. As used herein, the word “exemplary” means “serving as an example, instance, or illustration.” Thus, any embodiment described herein as “exemplary” is not necessarily to be construed as preferred or advantageous over other embodiments. All of the embodiments described herein are exemplary embodiments provided to enable persons skilled in the art to make or use the invention and not to limit the scope of the invention which is defined by the claims. Furthermore, there is no intention to be bound by any expressed or implied theory presented in the preceding technical field, background, brief summary, or the following detailed description.

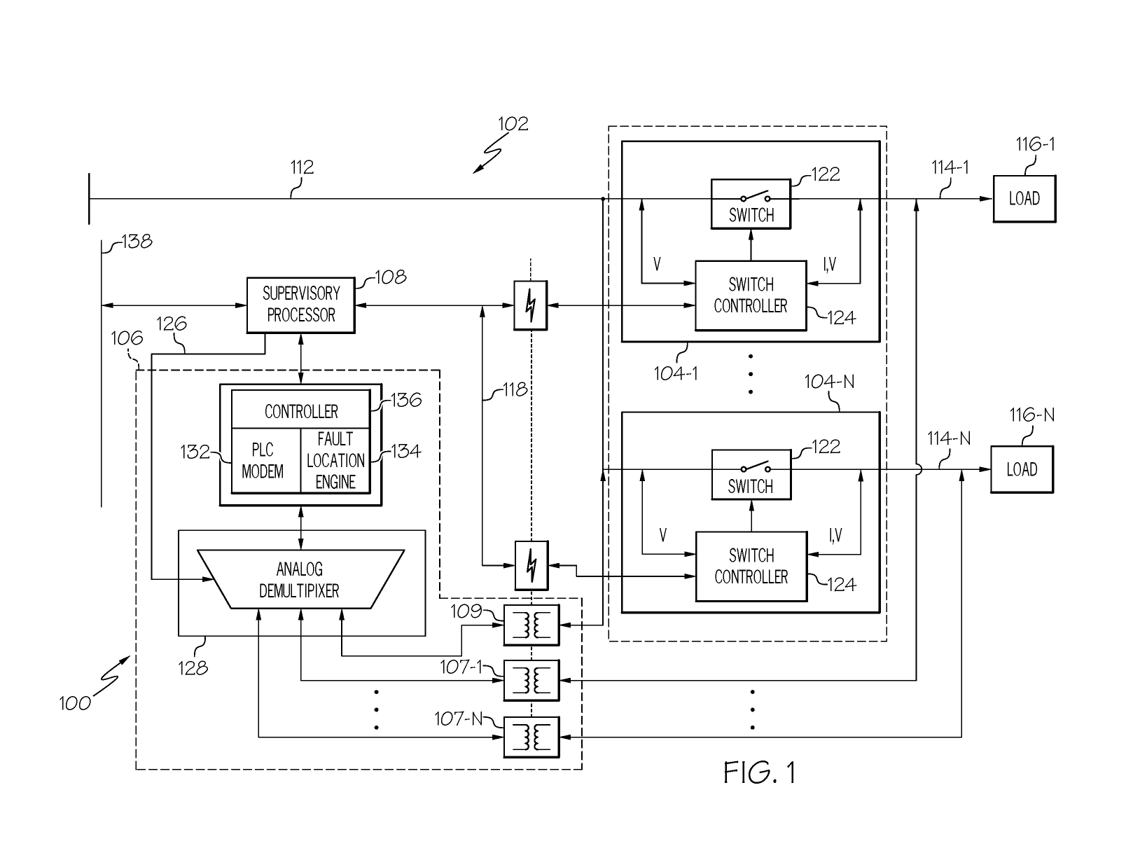

Referring to FIG. 1, a functional block diagram of one embodiment of a power line communication and real-time wiring fault location system 100 is depicted. The depicted system 100 is for, and is thus disposed within, a power distribution system 102. The system 100 includes at least a plurality of solid-state power controllers 104 (104-1, . . . 104-N), and a communication and fault location determination circuit 106. In the depicted embodiment, the system 100 also includes a supervisory processor 108.

The depicted power distribution system 102 includes an upstream power feeder line 112 and a plurality of load-end feeder lines 114 (114-1, . . . 114-N). As used herein, a load-end feed line 114 is an individual electrical conductor, such as a wire or other suitable conductor. Each load-end feeder line 114 is coupled to an electrical load 116 (116-1, . . . 116-N).

The solid-state power controllers 104 are independent and may, in some embodiments, be disposed on the same printed circuit board (PCB). Each solid-state power controller 104 is associated with a different one of the load-end feeder lines 114, and is coupled between its associated load-end feeder line 114 and the upstream power feeder line 112. Each solid-state power controller 104 is configured to selectively couple its associated load-end feeder line 114 to the upstream power feeder line 112, to thereby energize the electrical load 116 to which the associated load-end feeder line 114 is coupled. Each solid-state power controller 104 is also configured to detect an electrical fault on its associated load-end feeder line 114 or in the electrical load 116 to which the associated load-end feeder line is coupled. In the depicted embodiment, each solid-state power controller 104 is further configured, upon detecting an electrical fault, to supply a fault detection signal, via an internal serial data bus 118, to the supervisory processor 108.

The solid-state power controllers 104 may be variously configured to implement the above-described functions. In the depicted embodiment, however, each 104 includes a solid-state switch 122 and a switch controller 124. The solid-state switch 122 is coupled to receive switch commands and is operable, in response to the switch commands, to selectively couple its associated load-end feeder line 114 to the upstream power feeder line 112. It will be appreciated that the solid-state switches 122 may be implemented using any one of numerous known solid-state switching devices.

The switch controller 124 is configured to supply the switch commands to the solid-state switch 122, to provide the appropriate power commutation to the associated electrical load 116. The switch controller 124 is preferably configured to supply these switch commands in response to commands it receives from, for example, the supervisory processor 108, via the internal serial data bus 118. The switch controller 124 is also configured to detect an electrical fault on its associated load-end feeder line 114 or in the electrical load 116 and, in response, to supply the fault detection signal to the supervisory processor 108, and to turn off the solid-state switch 122. The switch controller 124 may detect an electrical fault based, for example, on sensed load current and/or voltage.

Each switch controller 124 may also be configured to collect and pre-process information characterizing the health condition of its associated load-end feeder line 114 and electrical load 116 via, for example, directly sampled load current and voltage and/or other information collected from non-illustrated remote sensors. The health condition may be supplied to the supervisory processor 108 via the internal serial data bus 118. Each switch controller 124 may also implement closed-loop control for certain loads (e.g. an aircraft heater) based on commands and feedback signals supplied from the supervisory processor 108.

The communication and fault location determination circuit 106 is coupled to each of the load-end feeder lines 114, via a plurality of load-end feeder line transformers 107 (107-1, . . . 107-N), and to the upstream power feeder line 112 via a power feeder line transformer 109. The communication and fault location determination circuit 106 is also coupled to receive a channel selection command 126. The communication and fault location determination circuit 106 is configured, in response to the channel selection command, to selectively transmit a fault location stimulation (or test) signal onto one of the load-end feeder lines 114, and more specifically, onto the load-end feeder line 114 associated with the channel selection command. The communication and fault location determination circuit 106 is further configured, in response to the channel selection command 126, to receive a reflected signal from the load-end feeder line 114 onto which the fault location stimulation signal was transmitted. In response to the reflected signal, the communication and fault location determination circuit 106 determines the location of the electrical fault. More specifically, and as will be described further below, the communication and fault location determination circuit 106 determines whether the location is on the load-end feeder line 114 or at the electrical load 116.

The communication and fault location determination circuit 106 is further configured, in response to the channel selection command, to selectively facilitate power line communication with one or more of the load-end feeder lines. That is, when it is desired to use one or more of the load-end feeder lines 114 as a communication channel, the communication and fault location determination circuit 106 implements the functionality to allow such communication.

It will be appreciated that the communication and fault location determination circuit 106 may be variously configured to implement the above-described functionality. In the depicted embodiment, however, it includes an analog multiplexer 128, a power line communication (PLC) modem 132, a fault location engine 134, and a communication and fault location determination circuit controller 136. The analog multiplexer 128 is coupled to receive the channel selection command from the supervisory controller 108 and is configured, in response thereto, to couple either the PLC modem 132 or the fault location engine 134 to the selected load-end feeder line 114.

The PLC modem 132 is configured to facilitate power line communication, and may be implemented using any one of numerous known PLC modems. More specifically, the PLC modem 132 is configured to selectively generate modulated signals, each of which is associated with the solid-state power controllers 104 or a different one of the load-end feeder lines 114 and associated electrical loads 116, and to transmit these modulated signals onto the upstream power feed line 112 or the selected load-end feeder lines 114. The PLC modem 132 is additionally coupled to receive and demodulate signals supplied thereto from solid-state power controllers 104 or the load-end feeder lines 114 and associated electrical loads 116.

The fault location engine 134 is configured to supply the fault location stimulation signal, to receive the reflected signal, and to determine the location of the electrical fault. The fault location engine 134 may be variously implemented, but in the depicted embodiment it is implemented as a spread spectrum time domain reflectometry (SSTDR) engine. Various SSTDR engines are known in the art, and enable the detection and location of numerous and varied types of electrical faults in a load-end feeder line 114 and electrical load 116, such as open and short circuits, and intermittent and developing faults, such as arcs. It will be appreciated, however, that the embodiments disclosed herein are not limited to SSTDR, but may also use any one of numerous reflectometry based fault location methodologies, such as time domain, frequency domain, spectral time domain, standing wave, etc.

The communication and fault location determination circuit controller 136 interfaces with the supervisory processor 108, and implements control and selection of either the PLC modem 132 or the fault location engine 134 and the associated functions. The controller 136 may also be configured to implement various built-in tests, and numerous other housekeeping functions. Although the controller 136 is depicted as an independent functional block in the communication and fault location determination circuit 106, it will be appreciated that its functionality could be included in the supervisory processor 108, an embodiment of which will now be described.

The supervisory processor 108 is mainly responsible for the control of, and communication with, the solid-state power controllers 104 via the internal serial data bus 118. The supervisory processor 108 is also responsible for the control of communications between a non-illustrated external interface terminal, such as an avionics controller, and the solid-state power controllers 104 via an external serial data bus 138. The supervisory processor 108 may also be configured to perform general housekeeping tasks, load configuration controls, and periodic built-in-tests (BIT). The supervisory processor 108 is also responsible for initiating power line communications with the solid-state power controllers 104 and the electrical loads 116 and various non-illustrated sensors. Power line communications with the solid-state power controllers 104 occurs via the upstream power feeder line 112, and power line communications with the electrical loads 116 and various non-illustrated sensors occurs via the load-end power feeder lines 114.

To implement the above-described responsibilities, the supervisory processor 108 is in operable communication with each of the solid-state power controllers 104, via the internal serial data bus 118, and with the communication and fault location determination circuit 106. The supervisory processor 108 is configured to supply the channel selection command 126 to the communication and fault location determination circuit 106, and more specifically to the analog multiplexer 128. The supervisory processor 108 is configured to supply the channel selection command in response to receiving a fault detection signal from one of the solid-state power controllers 104, or in response to a request to initiate power line communication. The request may originate from the non-illustrated external interface terminal, via the external serial data bus 138, or from one of the solid-state power controllers 104.

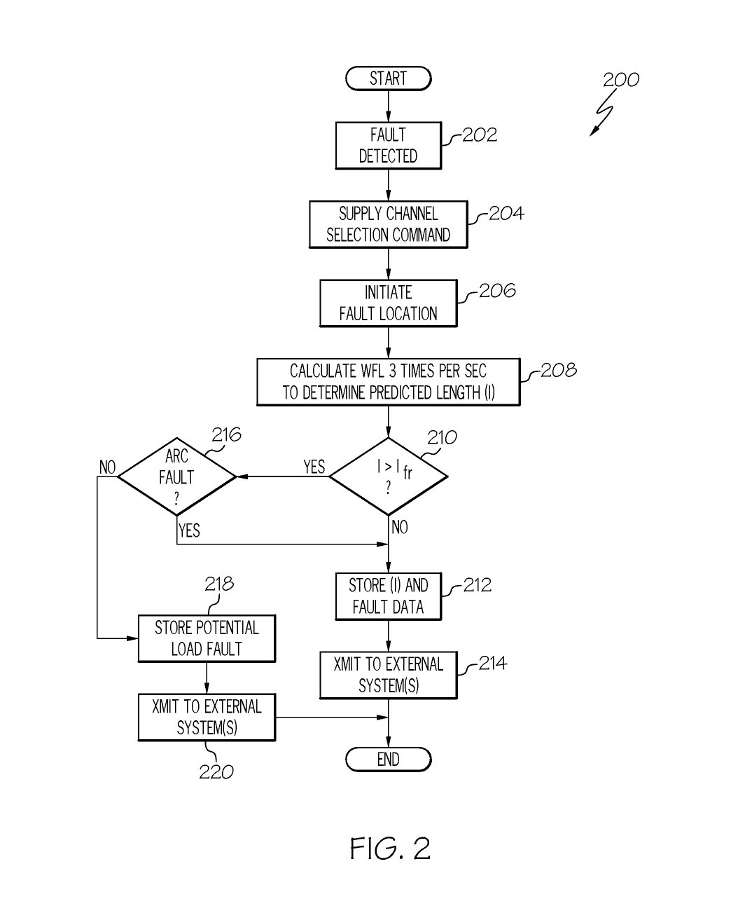

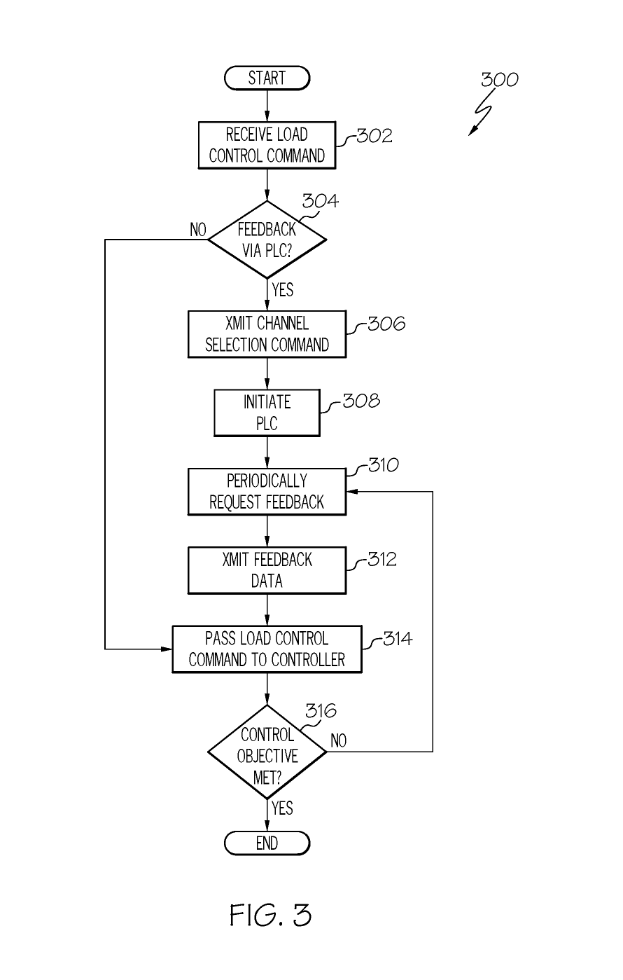

As described above, the power line communication and real-time wiring fault location system 100 may implement both wire fault location determination and power line communication functions. The processes that the system 100 carries out to implement each of these functions are depicted in flowchart form in FIGS. 2 and 3, respectively, and with reference thereto will now be described beginning with FIG. 2.

As depicted in FIG. 2, the wire fault location determination process 200 begins when one of the solid-state power controllers 104 detects a fault, sends a fault detection signal to the supervisory processor 108, and is turned off (202). The fault may be, for example, a failed power line communication and/or an arc fault trip.

Regardless of the cause of the fault, the supervisory processor 108, in response to the fault detection signal, supplies the channel selection command 126 to the communication and fault location determination circuit 106 (204). The communication and fault location determination circuit 106 in turn initiates a fault location procedure (206). In the depicted embodiment, this procedure entails transmitting fault location stimulation signals onto, and receiving reflected signals from, the associated load-end feeder line 114. The communication and fault location determination circuit 106, using the reflected signals, determines the location of the electrical fault. More specifically, at least in the depicted embodiment, the communication and fault location determination circuit 106 calculates a wire fault location (WFL) three times per second, and takes the average of the calculations to determine a predicted length (l) to the WFL location (208).

The predicted length (l) is then compared to a predetermined load-end feeder line reference length (l_{fr}) (210). If the predicted length is not greater than the load-end feeder line reference length, then the electrical fault is considered to be at the location in the load-end feeder line 114 that corresponds to the predicted length. The location prediction and fault data are then stored (212) and transmitted to external systems (214).

If the predicted length is greater than the load-end feeder line reference length (i.e., l>l_{fr}), then the electrical fault is considered to be either right at the electrical load 116 or in the electrical load itself. In such a case, the process then determines if the specific fault was an arc fault (216). If so, then the location prediction and fault data are stored (212) and transmitted to external systems (214). If the fault was not an arc fault, then the fault is stored as a potential load fault (218) and a message is transmitted to external systems (220).

Turning now to FIG. 3, an example process 300 that may include power line communication is depicted. The depicted process is an embodiment for executing load control of one of the electrical loads 116, and initiates upon the supervisory processor 108 receiving a load control command from either the external serial data bus 138 or from one of the electrical loads 116 via its associated solid-state power controller 104 and internal serial data bus 118 (302). In response to the command, the supervisory processor 108 determines whether feedback data via power line communication is required (304). If so, then the supervisory processor 108 transmits the appropriate channel selection command to the communication and fault location determination circuit 106 (306).

The communication and fault location determination circuit 106, in response to the channel selection command, initiates power line communication with the appropriate load-end power feeder line 114 (308). The supervisory controller 108 periodically requests feedback data from the appropriate load-end power feeder line 114 (310), and transmits the feedback data to the appropriate solid-state power controller 104 (312), via the internal serial data bus 118.

The supervisory processor 108 then passes the load control command to the appropriate solid-state power controller 104 (314), also via the internal serial data bus 118, and determines if the control objective met (316). If so, then the process ends. If not, then the process loops back to step 308 until the control objective is met.

As FIG. 3 also depicts, if the supervisory processor 108 determines that feedback data via power line communication is not required (304), then the process jumps directly to step 314, and runs until the control objective is met.

The power line communication and real-time wiring fault location system 100 described herein provides practical implementation of PLC and SSTDR technologies in an aircraft electric power distribution system, and provides effective and efficient control and maintenance functions for aircraft electric loads and wiring system.

In one embodiment, a power line communication and real-time wiring fault location system includes a power distribution system, a plurality of solid-state power controllers, and a communication and fault location determination circuit. The power distribution system includes an upstream power feeder line and a plurality of load-end feeder lines, and each load-end feeder line is coupled to an electrical load. Each solid-state power controller is associated with a different one of the load-end feeder lines and is coupled between its associated load-end feeder line and the upstream power feeder line. Each solid-state power controller is configured to (i) selectively couple its associated load-end feeder line to the upstream power feeder line and (ii) detect an electrical fault on its associated load-end feeder line or in the electrical load to which the associated load-end feeder line is coupled. The communication and fault location determination circuit is coupled to each of the load-end feeder lines. The communication and fault location determination circuit is adapted to receive a channel selection command and is configured, in response to the channel selection command, to selectively transmit a fault location stimulation signal onto one of the load-end feeder lines.

These aspects and other embodiments may include one or more of the following features. A supervisory processor may be in operable communication with each of the solid-state power controllers and with the communication and fault location determination circuit, and configured to supply the channel selection command to the communication and fault location determination circuit. Each solid-state power controller may be further configured, upon detecting an electrical fault, to supply a fault detection signal to the supervisory processor; and the supervisory processor may be configured, upon receipt of the fault detection signal, to supply the channel selection command. The solid-state switch may be coupled to receive switch commands and may be operable, in response to the switch commands, to selectively couple its associated load-end feeder line to the upstream power feeder line. A switch controller may be configured to supply the switch commands to the solid-state switch and to supply the fault detection signal to the supervisory processor. An internal serial data bus may be coupled between the supervisory processor and each of the solid-state power controllers. An external serial data bus may be coupled to the supervisory processor, and the supervisory processor may be responsive to commands supplied via the external serial data bus. A plurality of load-end feeder line transformers, each associated with a different one of the load-end feeder lines, may be coupled between its associated load-end feeder line and the communication and fault location determination circuit. A power feeder line transformer may be coupled between the upstream power feeder line and the communication and fault location determination circuit. The communication and fault location determination circuit may be further configured, in response to the channel selection command, to receive a reflected signal from the load-end feeder line onto which the fault location stimulation signal was transmitted and, in response to the reflected signal, determine a location of the electrical fault. The communication and fault location determination circuit may be further configured to determine whether the location is on the load-end feeder line or at the electrical load. The communication and fault location determination circuit may be further configured, in response to the channel selection command, to selectively facilitate power line communication with one or more of the load-end feeder lines. The communication and fault location determination circuit may include: a fault location engine configured to (i) supply the fault location stimulation signal, (ii) receive the reflected signal, and (iii) determine the location of the electrical fault; a power line communication modem configured to facilitate the power line communication; a communication and fault location determination circuit controller in operable communication with the fault location engine and the power line communication modem, the communication and fault location determination circuit controller configured to implement control of the fault location engine and the power line communication modem; and an analog multiplexer coupled to receive the channel selection command and configured, in response thereto, to couple one of the fault location engine and the power line communication controller to one of the load-end feeder lines.

In another embodiment, a power line communication and real-time wiring fault location system includes a power distribution system, a plurality of solid-state power controllers, a communication and fault location determination circuit, and a supervisory processor. The power distribution system includes an upstream power feeder line and a plurality of load-end feeder lines, and each load-end feeder line is coupled to an electrical load. Each solid-state power controller is associated with a different one of the load-end feeder lines and is coupled between its associated load-end feeder line and the upstream power feeder line. Each solid-state power controller is configured to (i) selectively couple its associated load-end feeder line to the upstream power feeder line and (ii) detect an electrical fault on its associated load-end feeder line or in the electrical load to which the associated load-end feeder line is coupled. The communication and fault location determination circuit is coupled to each of the load-end feeder lines. The communication and fault location determination circuit is coupled to receive a channel selection command and is configured, in response to the channel selection command, to (i) selectively transmit a fault location stimulation signal onto one of the load-end feeder lines and (ii) receive a reflected signal from the load-end feeder line and, in response to the reflected signal, determine a location of the electrical fault. The supervisory processor is in operable communication with each of the solid-state power controllers and with the communication and fault location determination circuit, and is configured to supply the channel selection command to the communication and fault location determination circuit.

These aspects and other embodiments may include one or more of the following features. The communication and fault location determination circuit may be further configured to determine whether the location is on the load-end feeder line or at the electrical load. The communication and fault location determination circuit may be further configured, in response to the channel selection command, to selectively facilitate power line communication with one or more of the load-end feeder lines. Each solid-state power controller may include a solid-state switch coupled to receive switch commands and operable, in response to the switch commands, to selectively couple its associated load-end feeder line to the upstream power feeder line, and a switch controller configured to supply the switch commands to the solid-state switch and, upon detecting an electrical fault, to supply a fault detection signal to the supervisory processor. The supervisory processor may be configured, upon receipt of the fault detection signal, to supply the channel selection command. An internal serial data bus may be coupled between the supervisory processor and each of the solid-state power controllers, an external serial data bus may be coupled to the supervisory processor, and the supervisory processor is responsive to commands supplied via the external serial data bus. A plurality of load-end feeder line transformers, each load-end feeder associated with a different one of the load-end feeder lines, may be coupled between its associated load-end feeder line and the communication and fault location determination circuit. A power feeder line transformer may be coupled between the upstream power feeder line and the communication and fault location determination circuit. The communication and fault location determination circuit may include: a fault location engine configured to (i) supply the fault location stimulation signal, (ii) receive the reflected signal, and (iii) determine the location of the electrical fault; a power line communication modem configured to facilitate the power line communication; a communication and fault location determination circuit controller in operable communication with the fault location engine and the power line communication modem, the communication and fault location determination circuit controller configured to implement control of the fault location engine and the power line communication modem; and an analog multiplexer coupled to receive the channel selection command and configured, in response thereto, to couple one of the fault location engine and the power line communication controller to one of the load-end feeder lines.

In yet another embodiment, a power line communication and real-time wiring fault location system includes a power distribution system, a plurality of solid-state power controllers, a supervisory processor, and a communication and fault location determination circuit. The power distribution system includes an upstream power feeder line and a plurality of load-end feeder lines, and each load-end feeder line is coupled to an electrical load. Each solid-state power controller is associated with a different one of the load-end feeder lines and is coupled between its associated load-end feeder line and the upstream power feeder line. Each solid-state power controller is configured to (i) selectively couple its associated load-end feeder line to the upstream power feeder line and (ii) detect an electrical fault on its associated load-end feeder line or in the electrical load to which the associated load-end feeder line is coupled. The supervisory processor is in operable communication with each of the solid-state power controllers and with the communication and fault location determination circuit, and is configured to selectively supply a channel selection command. The communication and fault location determination circuit is coupled to each of the load-end feeder lines. The communication and fault location determination circuit is coupled to receive the channel selection command and is configured, in response to the channel selection command, to: (i) selectively transmit a fault location stimulation signal onto one of the load-end feeder lines, (ii) receive a reflected signal from the load-end feeder line and, in response to the reflected signal, determine a location of the electrical fault, and (iii) selectively facilitate power line communication with one or more of the load-end feeder lines.

Those of skill in the art will appreciate that the various illustrative logical blocks, modules, circuits, and algorithm steps described in connection with the embodiments disclosed herein may be implemented as electronic hardware, computer software, or combinations of both. Some of the embodiments and implementations are described above in terms of functional and/or logical block components (or modules) and various processing steps. However, it should be appreciated that such block components (or modules) may be realized by any number of hardware, software, and/or firmware components configured to perform the specified functions. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present invention. For example, an embodiment of a system or a component may employ various integrated circuit components, e.g., memory elements, digital signal processing elements, logic elements, look-up tables, or the like, which may carry out a variety of functions under the control of one or more microprocessors or other control devices. In addition, those skilled in the art will appreciate that embodiments described herein are merely exemplary implementations.

The various illustrative logical blocks, modules, and circuits described in connection with the embodiments disclosed herein may be implemented or performed with a general purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general-purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The steps of a method or algorithm described in connection with the embodiments disclosed herein may be embodied directly in hardware, in a software module executed by a processor, or in a combination of the two. A software module may reside in RAM memory, flash memory, ROM memory, EPROM memory, EEPROM memory, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor. The processor and the storage medium may reside in an ASIC.

Techniques and technologies may be described herein in terms of functional and/or logical block components, and with reference to symbolic representations of operations, processing tasks, and functions that may be performed by various computing components or devices. Such operations, tasks, and functions are sometimes referred to as being computer-executed, computerized, software-implemented, or computer-implemented. In practice, one or more processor devices can carry out the described operations, tasks, and functions by manipulating electrical signals representing data bits at memory locations in the system memory, as well as other processing of signals. The memory locations where data bits are maintained are physical locations that have particular electrical, magnetic, optical, or organic properties corresponding to the data bits. It should be appreciated that the various block components shown in the figures may be realized by any number of hardware, software, and/or firmware components configured to perform the specified functions. For example, an embodiment of a system or a component may employ various integrated circuit components, e.g., memory elements, digital signal processing elements, logic elements, look-up tables, or the like, which may carry out a variety of functions under the control of one or more microprocessors or other control devices.

When implemented in software or firmware, various elements of the systems described herein are essentially the code segments or instructions that perform the various tasks. The program or code segments can be stored in a processor-readable medium or transmitted by a computer data signal embodied in a carrier wave over a transmission medium or communication path. The “computer-readable medium”, “processor-readable medium”, or “machine-readable medium” may include any medium that can store or transfer information. Examples of the processor-readable medium include an electronic circuit, a semiconductor memory device, a ROM, a flash memory, an erasable ROM (EROM), a floppy diskette, a CD-ROM, an optical disk, a hard disk, a fiber optic medium, a radio frequency (RF) link, or the like. The computer data signal may include any signal that can propagate over a transmission medium such as electronic network channels, optical fibers, air, electromagnetic paths, or RF links. The code segments may be downloaded via computer networks such as the Internet, an intranet, a LAN, or the like.

Some of the functional units described in this specification have been referred to as “modules” in order to more particularly emphasize their implementation independence. For example, functionality referred to herein as a module may be implemented wholly, or partially, as a hardware circuit comprising custom VLSI circuits or gate arrays, off-the-shelf semiconductors such as logic chips, transistors, or other discrete components. A module may also be implemented in programmable hardware devices such as field programmable gate arrays, programmable array logic, programmable logic devices, or the like. Modules may also be implemented in software for execution by various types of processors. An identified module of executable code may, for instance, comprise one or more physical or logical modules of computer instructions that may, for instance, be organized as an object, procedure, or function. Nevertheless, the executables of an identified module need not be physically located together, but may comprise disparate instructions stored in different locations that, when joined logically together, comprise the module and achieve the stated purpose for the module. Indeed, a module of executable code may be a single instruction, or many instructions, and may even be distributed over several different code segments, among different programs, and across several memory devices. Similarly, operational data may be embodied in any suitable form and organized within any suitable type of data structure. The operational data may be collected as a single data set, or may be distributed over different locations including over different storage devices, and may exist, at least partially, merely as electronic signals on a system or network.

In this document, relational terms such as first and second, and the like may be used solely to distinguish one entity or action from another entity or action without necessarily requiring or implying any actual such relationship or order between such entities or actions. Numerical ordinals such as “first,” “second,” “third,” etc. simply denote different singles of a plurality and do not imply any order or sequence unless specifically defined by the claim language. The sequence of the text in any of the claims does not imply that process steps must be performed in a temporal or logical order according to such sequence unless it is specifically defined by the language of the claim. The process steps may be interchanged in any order without departing from the scope of the invention as long as such an interchange does not contradict the claim language and is not logically nonsensical.

Furthermore, depending on the context, words such as “connect” or “coupled to” used in describing a relationship between different elements do not imply that a direct physical connection must be made between these elements. For example, two elements may be connected to each other physically, electronically, logically, or in any other manner, through one or more additional elements.

While at least one exemplary embodiment has been presented in the foregoing detailed description of the invention, it should be appreciated that a vast number of variations exist. It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing an exemplary embodiment of the invention. It being understood that various changes may be made in the function and arrangement of elements described in an exemplary embodiment without departing from the scope of the invention as set forth in the appended claims.

What is claimed is:

1. A power line communication and real-time wiring fault location system, comprising:
a power distribution system including an upstream power feeder line and a plurality of load-end feeder lines, each load-end feeder line coupled to an electrical load;
a plurality of solid-state power controllers, each solid-state power controller associated with a different one of the load-end feeder lines and coupled between its associated load-end feeder line and the upstream power feeder line, each solid-state power controller configured to (i) selectively couple its associated load-end feeder line to the upstream power feeder line and (ii) detect an electrical fault on its associated load-end feeder line or in the electrical load to which the associated load-end feeder line is coupled; and
a communication and fault location determination circuit coupled to each of the load-end feeder lines, the communication and fault location determination circuit adapted to receive a channel selection command and configured, in response to the channel selection command, to selectively transmit a fault location stimulation signal onto one of the load-end feeder lines.

2. The system of claim 1, further comprising:
a supervisory processor in operable communication with each of the solid-state power controllers and with the communication and fault location determination circuit, the supervisory processor configured to supply the channel selection command to the communication and fault location determination circuit.

3. The system of claim 2, wherein:
each solid-state power controller is further configured, upon detecting an electrical fault, to supply a fault detection signal to the supervisory processor; and
the supervisory processor is configured, upon receipt of the fault detection signal, to supply the channel selection command.

4. The system of claim 2, wherein each solid-state power controller comprises:
a solid-state switch coupled to receive switch commands and operable, in response to the switch commands, to selectively couple its associated load-end feeder line to the upstream power feeder line; and
a switch controller configured to supply the switch commands to the solid-state switch and to supply the fault detection signal to the supervisory processor.

5. The system of claim 4, further comprising:
an internal serial data bus coupled between the supervisory processor and each of the solid-state power controllers.

6. The system of claim 2, further comprising:
an external serial data bus coupled to the supervisory processor,
wherein the supervisory processor is responsive to commands supplied via the external serial data bus.

7. The system of claim 1, further comprising:
a plurality of load-end feeder line transformers, each load-end feeder line transformer associated with a different one of the load-end feeder lines and coupled between its associated load-end feeder line and the communication and fault location determination circuit.

8. The system of claim 7, further comprising:
a power feeder line transformer coupled between the upstream power feeder line and the communication and fault location determination circuit.

9. The system of claim 1, wherein the communication and fault location determination circuit is further configured, in response to the channel selection command, to receive a reflected signal from the load-end feeder line onto which the fault location stimulation signal was transmitted and, in response to the reflected signal, determine a location of the electrical fault.

10. The system of claim 9, wherein the communication and fault location determination circuit is further configured to determine whether the location is on the load-end feeder line or at the electrical load.

11. The system of claim 9, wherein the communication and fault location determination circuit is further configured, in response to the channel selection command, to selectively facilitate power line communication with one or more of the load-end feeder lines.

12. The system of claim 9, wherein the communication and fault location determination circuit comprises:
a fault location engine configured to (i) supply the fault location stimulation signal, (ii) receive the reflected signal, and (iii) determine the location of the electrical fault;
a power line communication modem configured to facilitate the power line communication;
a communication and fault location determination circuit controller in operable communication with the fault location engine and the power line communication modem, the communication and fault location determination circuit controller configured to implement control of the fault location engine and the power line communication modem; and
an analog multiplexer coupled to receive the channel selection command and configured, in response thereto, to couple one of the fault location engine and the power line communication controller to one of the load-end feeder lines.

13. A power line communication and real-time wiring fault location system, comprising:
a power distribution system including an upstream power feeder line and a plurality of load-end feeder lines, each load-end feeder line coupled to an electrical load;
a plurality of solid-state power controllers, each solid-state power controller associated with a different one of the load-end feeder lines and coupled between its associated load-end feeder line and the upstream power feeder line, each solid-state power controller configured to (i) selectively couple its associated load-end feeder line to the upstream power feeder line and (ii) detect an electrical fault on its associated load-end feeder line or in the electrical load to which the associated load-end feeder line is coupled;
a communication and fault location determination circuit coupled to each of the load-end feeder lines, the communication and fault location determination circuit coupled to receive a channel selection command and configured, in response to the channel selection command, to (i) selectively transmit a fault location stimulation signal onto one of the load-end feeder lines and (ii) receive a reflected signal from the load-end feeder line and, in response to the reflected signal, determine a location of the electrical fault; and
a supervisory processor in operable communication with each of the solid-state power controllers and with the communication and fault location determination circuit, the supervisory processor configured to supply the channel selection command to the communication and fault location determination circuit.

14. The system of claim 13, wherein the communication and fault location determination circuit is further configured to determine whether the location is on the load-end feeder line or at the electrical load.

15. The system of claim 13, wherein the communication and fault location determination circuit is further configured, in response to the channel selection command, to selectively facilitate power line communication with one or more of the load-end feeder lines.

16. The system of claim 13, wherein each solid-state power controller comprises:
a solid-state switch coupled to receive switch commands and operable, in response to the switch commands, to selectively couple its associated load-end feeder line to the upstream power feeder line; and
a switch controller configured to supply the switch commands to the solid-state switch and, upon detecting an electrical fault, to supply a fault detection signal to the supervisory processor,
wherein the supervisory processor is configured, upon receipt of the fault detection signal, to supply the channel selection command.

17. The system of claim 13, further comprising:
an internal serial data bus coupled between the supervisory processor and each of the solid-state power controllers; and
an external serial data bus coupled to the supervisory processor,
wherein the supervisory processor is responsive to commands supplied via the external serial data bus.

18. The system of claim 13, further comprising:
a plurality of load-end feeder line transformers, each load-end feeder line transformer associated with a different one of the load-end feeder lines and coupled between its associated load-end feeder line and the communication and fault location determination circuit; and
a power feeder line transformer coupled between the upstream power feeder line and the communication and fault location determination circuit.

19. The system of claim 13, wherein the communication and fault location determination circuit comprises:
a fault location engine configured to (i) supply the fault location stimulation signal, (ii) receive the reflected signal, and (iii) determine the location of the electrical fault;
a power line communication modem configured to facilitate the power line communication;
a communication and fault location determination circuit controller in operable communication with the fault location engine and the power line communication modem, the communication and fault location determination circuit controller configured to implement control of the fault location engine and the power line communication modem; and
an analog multiplexer coupled to receive the channel selection command and configured, in response thereto, to couple one of the fault location engine and the power line communication controller to one of the load-end feeder lines.

20. A power line communication and real-time wiring fault location system, comprising:
a power distribution system including an upstream power feeder line and a plurality of load-end feeder lines, each load-end feeder line coupled to an electrical load;
a plurality of solid-state power controllers, each solid-state power controller associated with a different one of the load-end feeder lines and coupled between its associated load-end feeder line and the upstream power feeder line, each solid-state power controller configured to (i) selectively couple its associated load-end feeder line to the upstream power feeder line and (ii) detect an electrical fault on its associated load-end feeder line or in the electrical load to which the associated load-end feeder line is coupled;
a supervisory processor in operable communication with each of the solid-state power controllers and with the communication and fault location determination circuit, the supervisory processor configured to selectively supply a channel selection command; and
a communication and fault location determination circuit coupled to each of the load-end feeder lines, the communication and fault location determination circuit coupled to receive the channel selection command and configured, in response to the channel selection command, to:
(i) selectively transmit a fault location stimulation signal onto one of the load-end feeder lines,
(ii) receive a reflected signal from the load-end feeder line and, in response to the reflected signal, determine a location of the electrical fault, and
(iii) selectively facilitate power line communication with one or more of the load-end feeder lines.
